(19) United States
(12) Patent Application Publication
(10) Pub. No.: US 2024/0120452 A1
(43) Pub. Date: Apr. 11, 2024

(54) REFLECTORS FOR SUPPORT STRUCTURES IN LIGHT-EMITTING DIODE PACKAGES

(71) Applicant: CreeLED, Inc., Durham, NC (US)

(72) Inventors: Derek Miller, Columbus, OH (US); Michael Check, Holly Springs, NC (US); Colin Blakely, Raleigh, NC (US)

(21) Appl. No.: 18/045,508

(22) Filed: Oct. 11, 2022

(51) Int. Cl. H01L 33/60; H01L 23/00; H01L 33/48

(52) U.S. Cl. CPC H01L 33/60; H01L 24/29; H01L 33/483; H01L 24/32; H01L 2224/29083; H01L 2224/29144; H01L 2224/29147; H01L 2224/29155; H01L 2224/29164; H01L 2224/32155; H01L 2924/0132; H01L 2924/12041

(57) ABSTRACT

Solid-state lighting devices including light-emitting diodes (LEDs) and, more particularly, reflectors for support structures in LED packages are disclosed. Support structures include arrangements of dielectric reflectors relative to LED chips and electrically conductive traces that are patterned on a submount. Dielectric reflectors include multiple dielectric layer structures that form a distributed Bragg reflector or, in some instances, an aperiodic Bragg reflector. Such dielectric reflectors may be arranged one or more of the electrically conductive traces and on portions of the submount uncovered by the electrically conducive traces to provide increased reflectivity across a variety of wavelengths provided by LED chips, including wavelengths in the ultraviolet spectrum.

### FIELD OF THE DISCLOSURE

The present disclosure relates to solid-state lighting devices including light-emitting diodes (LEDs), and more particularly to reflectors for support structures in LED packages.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, aluminum nitride, gallium arsenide-based materials, and/or from organic semiconductor materials. Photons generated by the active region are initiated in all directions.

Typically, it is desirable to operate LEDs at the highest light emission efficiency possible, which can be measured by the emission intensity in relation to the output power (e.g., in lumens per watt). A practical goal to enhance emission efficiency is to maximize extraction of light emitted by the active region in the direction of the desired transmission of light. Light extraction and external quantum efficiency of an LED can be limited by a number of factors, including internal reflection. LED packages have been developed that can provide mechanical support, electrical connections, and encapsulation for LED emitters. Light emissions that exit surfaces of LED emitters may then interact with elements or surfaces of corresponding LED packages, thereby increasing opportunities for light loss. Additionally, various operating conditions and wavelengths of emitted light can cause degradation of various materials conventionally used for LED packages. As such, there can be challenges in producing high quality light with desired emission characteristics while also providing high light emission efficiency in LED packages.

The art continues to seek improved LEDs and solid-state lighting devices having desirable illumination characteristics capable of overcoming challenges associated with conventional lighting devices.

### SUMMARY

The present disclosure relates to solid-state lighting devices including light-emitting diodes (LEDs), and more particularly to reflectors for support structures in LED packages. Support structures include arrangements of dielectric reflectors relative to LED chips and electrically conductive traces that are patterned on a submount. Dielectric reflectors include multiple dielectric layer structures that form a distributed Bragg reflector or, in some instances, an aperiodic Bragg reflector. Such dielectric reflectors may be arranged on one or more of the electrically conductive traces and on portions of the submount uncovered by the electrically conducive traces to provide increased reflectivity across a variety of wavelengths provided by LED chips, including wavelengths in the ultraviolet spectrum.

In one aspect, an LED package comprises: a submount comprising a first face and a second face that opposes the first face; at least one LED chip on the first face of the submount; a cover structure arranged over the at least one LED chip; a patterned trace on the first face of the submount, the cover structure being attached to the patterned trace at a cover structure mounting area that is outside of at least one die attach pad; and a dielectric reflector on a portion of the patterned trace that is between the at least one die attach pad and the cover structure mounting area, the dielectric reflector comprising a distributed Bragg reflector. In certain embodiments, the distributed Bragg reflector is an aperiodic distributed Bragg reflector. In certain embodiments, the aperiodic distributed Bragg reflector comprises a plurality of dielectric layers; and each dielectric layer of the plurality of dielectric layers comprises a unique optical thickness relative to other dielectric layers of the plurality of dielectric layers. In certain embodiments, the plurality of dielectric layers comprises alternating dielectric layers of a first material type and a second material type. In certain embodiments, the dielectric reflector is further on a portion of the submount that is uncovered by the patterned trace and the at least one LED chip. In certain embodiments, the dielectric reflector is further arranged between the at least one LED chip and the submount in a gap formed by the patterned trace along the at least one die attach pad. In certain embodiments, the at least one LED chip is configured to provide a peak wavelength in a range from 200 nm to 400 nm.

In another aspect, an LED package comprises: a submount comprising a first face and a second face that opposes the first face; at least one LED chip on the first face of the submount; a cover structure arranged over the at least one LED chip, the cover structure being mounted to the submount at a cover structure mounting area that is spaced from a peripheral boundary of the at least one LED chip; a patterned trace on the first face of the submount, the patterned trace forming at least one die attach pad for the at least one LED chip; and a dielectric reflector on a portion of the submount that is laterally adjacent the patterned trace, the dielectric reflector comprising a distributed Bragg reflector. In certain embodiments, the dielectric reflector is further arranged on a portion of the patterned trace. In certain embodiments, the dielectric reflector is further arranged between the cover structure and the submount at the cover structure mounting area. In certain embodiments, the distributed Bragg reflector is an aperiodic distributed Bragg reflector; the aperiodic distributed Bragg reflector comprises a plurality of dielectric layers; and each dielectric layer of the plurality of dielectric layers comprises a unique optical thickness relative to other dielectric layers of the plurality of dielectric layers. In certain embodiments, the plurality of dielectric layers comprises alternating dielectric layers of a first material type and a second material type. In certain embodiments, a dielectric layer with a largest optical thickness of the plurality of dielectric layers is positioned to be spaced away from a top surface of the aperiodic distributed Bragg reflector and within an interior of the aperiodic distributed Bragg reflector. In certain embodiments, the at least one LED chip is configured to provide a peak wavelength in a range from 200 nm to 400 nm

In another aspect, an LED package comprises: a submount comprising a first face and a second face that opposes the first face; at least one LED chip on the first face of the submount; a patterned trace on the first face of the submount; and a dielectric reflector on a portion of the patterned trace and on a portion of the submount that is laterally adjacent the patterned trace, the dielectric reflector comprising a distributed Bragg reflector. In certain embodiments, the distributed Bragg reflector is an aperiodic distributed Bragg reflector. In certain embodiments, the aperiodic distributed Bragg reflector comprises a plurality of dielectric layers; and each dielectric layer of the plurality of dielectric layers comprises a unique optical thickness relative to other dielectric layers of the plurality of dielectric layers. In certain embodiments, the plurality of dielectric layers comprises alternating dielectric layers of a first material type and a second material type. In certain embodiments, a dielectric layer with a largest optical thickness of the plurality of dielectric layers is positioned to be spaced away from a top surface of the aperiodic distributed Bragg reflector and within an interior of the aperiodic distributed Bragg reflector. In certain embodiments, the patterned trace comprises at least one die attach pad for the at least one LED chip; and the dielectric reflector is further arranged between the at least one LED chip and the submount in a gap formed by the patterned trace along the at least one die attach pad. In certain embodiments, the at least one LED chip is configured to provide a peak wavelength in a range from 200 nm to 400 nm. The LED package may further comprise a cover structure arranged over submount to form a cavity over the at least one LED chip. The LED package may further comprise a reflector structure arranged between the cover structure and the submount, wherein a sidewall of the reflector structure bounds a portion of the cavity. In certain embodiments, the dielectric reflector is arranged on the sidewall of the reflector structure. In certain embodiments, the dielectric reflector is arranged between the reflector structure and the submount

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a top view of a portion of a light-emitting diode (LED) package that includes portions of a first patterned trace, referred to herein collectively as the first patterned trace, and a dielectric reflector that are provided on a submount according to principles of the present disclosure.

FIG. 2 is a top view of a portion of an LED package that is similar to the LED package of FIG. 1 for an alternative layout of the dielectric reflector.

FIG. 3 is a cross-sectional view of an exemplary dielectric reflector that may be provided for any of the embodiments of the present disclosure.

FIG. 4A is a cross-sectional view of a structure that includes the first patterned trace and the dielectric reflector.

FIG. 4B is a cross-sectional view of a structure for an alternative arrangement of the first patterned trace and the dielectric reflector.

FIG. 5A is a cross-sectional view of an LED package taken along a portion of the LED package that is similar to the sectional line A-A of FIG. 1 and wherein the LED package is assembled with at least one LED chip and a cover structure according to principles of the present disclosure.

FIG. 5B is a cross-sectional view of the LED package of FIG. 5A taken along a portion of the LED package that is similar to the sectional line B-B of FIG. 1 in an area that is outside the LED chip.

FIG. 6A is a cross-sectional view of an LED package that is similar to the LED package of FIGS. 5A and 5B with an alternative arrangement of the cover structure.

FIG. 6B is a cross-sectional view of the LED package of FIG. 6A taken along a portion of the LED package that is similar to the sectional line B-B of FIG. 1 in an area that is outside the LED chip.

FIG. 7A is a cross-sectional view of an LED package taken along a portion of the LED package that is similar to the sectional line A-A of FIG. 1 and where the dielectric reflector is provided between the cover structure and the submount in the cover structure mounting area.

FIG. 7B is a cross-sectional view of the LED package of FIG. 7A taken along a portion of the LED package that is similar to the sectional line B-B of FIG. 1.

FIG. 8A is a cross-sectional view of an LED package that is similar to the LED package of FIGS. 6A and 6B and where the dielectric reflector is provided between the cover structure and the submount in the cover structure mounting area.

FIG. 8B is a cross-sectional view of the LED package of FIG. 8A taken along a portion of the LED package that is similar to the sectional line B-B of FIG. 1 in an area that is outside the LED chip.

FIG. 9 is a cross-sectional view of an LED package that is similar to the LED package of FIG. 5A and where the dielectric reflector is further provided on portions of the submount that are laterally adjacent the first patterned trace.

FIG. 10 is a cross-sectional view of an LED package that is similar to the LED package of FIG. 7A and where the dielectric reflector is further provided on portions of the submount that are laterally adjacent the first patterned trace.

FIG. 11 is a cross-sectional view of an LED package taken along a portion of the LED package that is similar to the sectional line A-A of FIG. 1 and wherein the first patterned trace is not provided in the cover structure mounting area.

FIG. 12 is a cross-sectional view of an LED package that is similar to the LED package of FIG. 11 except the dielectric reflector is not positioned within the cover structure mounting area.

FIG. 13 is a cross-sectional view of an LED package taken along a portion of the LED package that is similar to the sectional line A-A of FIG. 1 and where the LED package includes a reflector structure arranged between the cover structure and the submount.

FIG. 14 is a cross-sectional view of an LED package that is similar to the LED package of FIG. 13 and where the dielectric reflector extends on the first patterned trace in a position that is between the reflector structure and the submount.

FIG. 15 is a cross-sectional view of an LED package that is similar to the LED package of FIG. 13 and where the dielectric reflector extends along sidewalls of the reflector structure.

FIG. 16 is a cross-sectional view of an LED package that is similar to the LED package of FIG. 15 and where the dielectric reflector extends along the sidewalls of the reflector structure and between the reflector structure and the first patterned trace.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs), and more particularly to reflectors for support structures in LED packages. Support structures include arrangements of dielectric reflectors relative to LED chips and electrically conductive traces that are patterned on a submount. Dielectric reflectors include multiple dielectric layer structures that form a distributed Bragg reflector or, in some instances, an aperiodic Bragg reflector. Such dielectric reflectors may be arranged on one or more of the electrically conductive traces and on portions of the submount uncovered by the electrically conducive traces to provide increased reflectivity across a variety of wavelengths provided by LED chips, including wavelengths in the ultraviolet (UV) spectrum.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include silicon carbide (SiC), organic semiconductor materials, and other Group III-V systems such as gallium phosphide (GaP), gallium arsenide (GaAs), and related compounds.

The active LED structure may be grown on a growth substrate that can include many materials, such as sapphire, SiC, aluminum nitride (AlN), and GaN. SiC has certain advantages, such as a closer crystal lattice match to Group III nitrides than other substrates and results in Group III nitride films of high quality. SiC also has a very high thermal conductivity so that the total output power of Group III nitride devices on SiC is not limited by the thermal dissipation of the substrate. Sapphire is another common substrate for Group III nitrides and also has certain advantages, including being lower cost, having established manufacturing processes, and having good light-transmissive optical properties.

Different embodiments of the active LED structure can emit different wavelengths of light depending on the composition of the active layer and n-type and p-type layers. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 650 nm. In certain embodiments, the active LED structure may be configured to emit light that is outside the visible spectrum, including one or more portions of the UV spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

Light emitted by the active layer or region of an LED chip may typically travel in a variety of directions. For targeted directional applications, internal mirrors or external reflective surfaces may be employed to redirect as much light as possible toward a desired emission direction. Internal mirrors may include single or multiple layers. Some multi-layer mirrors include a metal reflector layer and a dielectric reflector layer, wherein the dielectric reflector layer is arranged between the metal reflector layer and a plurality of semiconductor layers. A passivation layer is arranged between the metal reflector layer and first and second electrical contacts, wherein the first electrical contact is arranged in conductive electrical communication with a first semiconductor layer, and the second electrical contact is arranged in conductive electrical communication with a second semiconductor layer. For single or multi-layer mirrors including surfaces exhibiting less than 100% reflectivity, some light may be absorbed by the mirror. Additionally, light that is redirected through the active LED structure may be absorbed by other layers or elements within the LED chip.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure may be useful for LED chips having a variety of geometries, including flip-chip geometries. Flip-chip structures for LED chips typically include anode and cathode connections that are made from a same side or face of the LED chip. The anode and cathode side is typically structured as a mounting face of the LED chip for flip-chip mounting to another surface, such as a printed circuit board. In this regard, the anode and cathode connections on the mounting face serve to mechanically bond and electrically couple the LED chip to the other surface. When flip-chip mounted, the opposing side or face of the LED chip corresponds with a light-emitting face that is oriented toward an intended emission direction. In certain embodiments, a growth substrate for the LED chip may form and/or be adjacent to the light-emitting face when flip-chip mounted. During chip fabrication, the active LED structure may be epitaxially grown on the growth substrate.

According to aspects of the present disclosure, LED packages may include one or more elements, such as lumiphoric materials or phosphors for wavelength conversion, encapsulants, light-altering materials, lenses, and electrical contacts, among others, that are provided with one or more LED chips. In certain aspects, an LED package may include a support member, such as a submount or a lead frame. Light-altering materials may be arranged within LED packages to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent.

Aspects of the present disclosure are provided that include support structures for LED packages. A support structure may refer to a structure of an LED package that supports one or more other elements of the LED package, including but not limited to LED chips and cover structures. In certain embodiments, a support structure may include a submount on which an LED chip is mounted. Suitable materials for a submount include, but are not limited to, ceramic materials such as aluminum oxide or alumina, AlN, or organic insulators like polyimide (PI) and polyphthalamide (PPA). In other embodiments a submount may comprise a printed circuit board (PCB), sapphire, Si, or any other suitable material. For PCB embodiments, different PCB types can be used such as standard FR-4 PCB, metal core PCB, or any other type of PCB. In still further embodiments, the support structure may embody a lead frame structure. Aspects of the present disclosure are provided in the context of support structures for LED chips that may emit light in any number of wavelength ranges, including wavelengths within UV and/or visible light spectrums.

UV LEDs are of particular interest for use in applications related to the disinfection of microorganisms in air, water, and on surfaces, among others. In other applications, UV LEDs may also be provided with one or more lumiphoric materials to provide aggregated broad emissions with improved color quality in the visible spectrum. Certain embodiments of the present disclosure may be well suited for applications where LED emissions are provided in one or more of the UV-A, UV-B, and UV-C wavelength ranges. Lower peak wavelengths, such as peak wavelengths in one or more of the UV-B and the UV-C wavelength ranges, may have high energy levels that can lead to breakdown of materials commonly used in other LED packages, including silicone, polymers, and/or other organic materials that are commonly used as encapsulants and/or binders for reflective particles and/or lumiphoric materials. Cover structures for UV-based LED packages may also need to provide protection from external environmental exposure, such as providing hermetic sealing and the like. As used herein, a hermetic seal generally refers to a seal that is airtight and watertight, thereby preventing the passage of air, gases, and/or liquids. In this regard, organic materials, such as silicone and epoxies, are not considered hermetic seals due to air permeability. In this manner, cover structures for UV LEDs may include at least one of glass, quartz, and/or ceramic materials that provide reduced breakdown from exposure to UV emissions while also being able to be attached or otherwise bonded to package support structures to hermetically seal underlying LED chips.

Support structures for LED packages may include one or more electrically conductive materials that may provide electrical connections to LED chips. Electrically conductive materials may be provided as metal traces or patterned metal traces on a submount, or the electrically conductive materials may form a lead frame structure that may or may not include a corresponding submount. The electrically conductive materials may include any number of materials, including copper (Cu) or alloys thereof, nickel (Ni) or alloys thereof, nickel chromium (NiCr), gold (Au) or alloys thereof, electroless Au, electroless silver (Ag), NiAg, Al or alloys thereof, titanium tungsten (TiW), titanium tungsten nitride (TiWN), electroless nickel electroless palladium immersion gold (ENEPIG), electroless nickel immersion gold (ENIG), hot air solder leveling (HASL), and organic solderability preservative (OSP). In certain embodiments, the electrically conductive materials may include ENEPIG or ENIG that include a top layer of Au. In other embodiments, electrically conductive materials may include a top layer of Ag. For UV-B and UV-C wavelength spectrums, Au and Ag exhibit poor reflectivity (e.g., about 20% to 40% reflectivity). In such embodiments, a layer with increased reflectivity relative to UV emissions, such as Al, may be arranged on or otherwise incorporated with the electrically conductive materials.

According to principles disclosed herein, arrangements of dielectric reflectors provide further increased reflectivity for LED packages. In particular embodiments, the dielectric reflectors may be configured to provide increased reflectivity for certain wavelengths, such as UV wavelengths, while also being composed of materials that are resistant to degradation associated with UV exposure. As will be later described in greater detail, dielectric reflectors may include multiple layer structures that form distributed Bragg reflectors or even aperiodic distributed Bragg reflectors. Such dielectric reflectors may be provided on patterned metal traces and/or on portions of a package submount that are between patterned metal traces, thereby providing increased reflective surfaces without electrically shorting neighboring electrical traces.

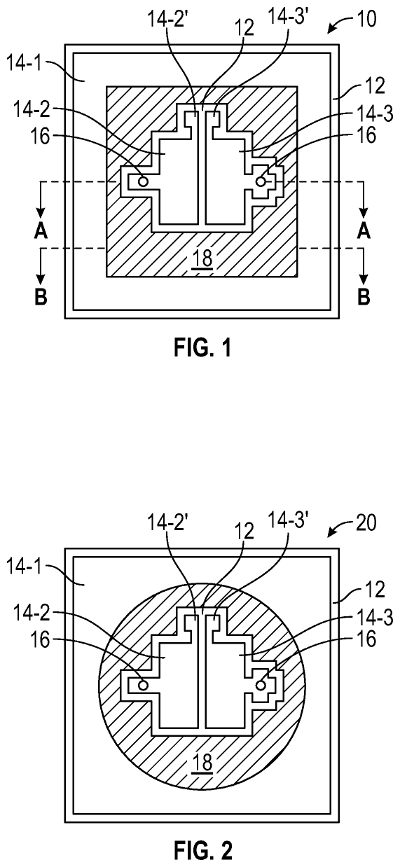

FIG. 1 is a top view of a portion of an LED package 10 that includes portions 14-1 to 14-3 of a first patterned trace, referred to herein collectively as the first patterned trace 14, and a dielectric reflector 18 that are provided on a submount 12 according to principles of the present disclosure. As used herein the submount 12 is a form of a support structure for the LED package 10. The first patterned trace 14 may form several discontinuous portions or traces 14-1 to 14-3 on the submount 12. For example, the discontinuous portions or traces 14-2 and 14-3 of the first patterned trace 14 may form a die attach pad for an LED chip where one of the discontinuous portions 14-2, 14-3 forms an anode pad of the die attach pad, and the other of the discontinuous portions 14-2, 14-3 forms a corresponding cathode pad of the die attach pad. In this manner, an LED chip may be flip-chip mounted to the die attach pad. Vias 16 may be provided that electrically connect the discontinuous portions 14-2, 14-3 to corresponding electrical connections on a backside or bottom face of the submount 12. In certain embodiments, protrusions 14-2′, 14-3′ of the discontinuous portions 14-2, 14-3 may extend away from the die attach pad area to form an attach area for another element, such as an electrical overstress element (e.g., ESD chip, Zener diode, etc.) that may be coupled in parallel with the LED chip. As illustrated, portions of the submount 12 between and around the discontinuous portions 14-2, 14-3 are devoid or uncovered by the first patterned trace 14. In certain embodiments, the discontinuous portion 14-1 may be provided on the submount 12 around a perimeter of the discontinuous portions 14-2, 14-3.

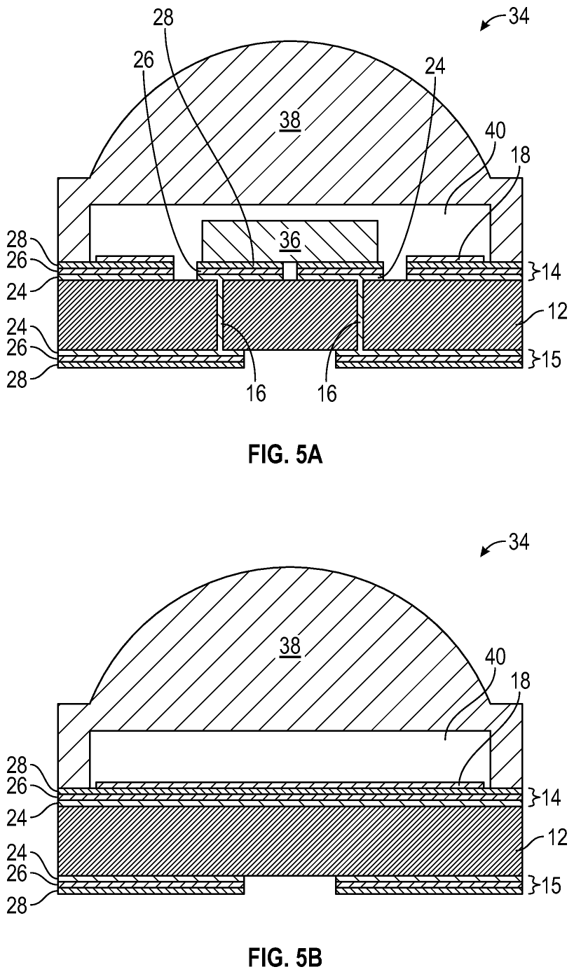

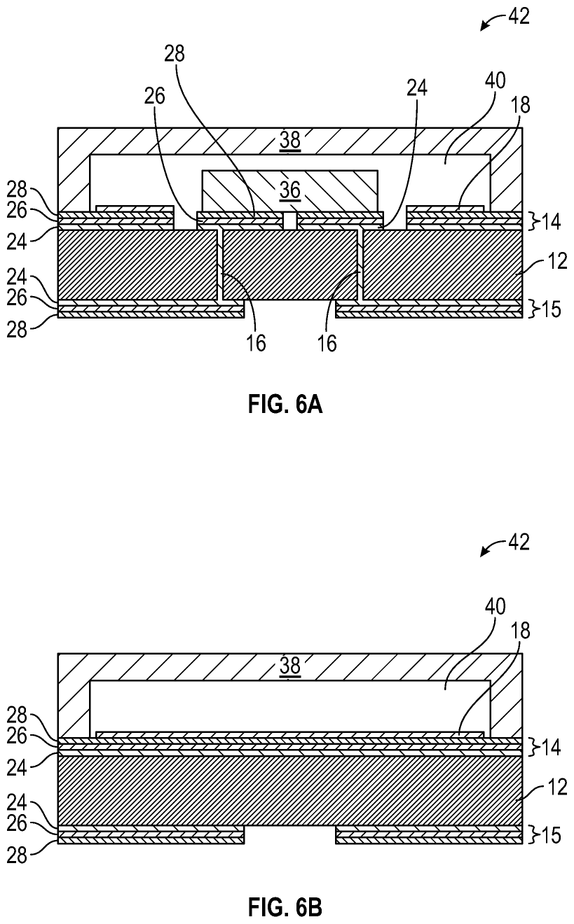

The first patterned trace 14 may include one or more layers of copper, gold, silver, ENEPIG, ENIG, and the like that exhibit reduced reflectivity for UV-B and UV-C emissions. In certain embodiments, the dielectric reflector 18 is selectively provided on the first patterned trace 14. In FIG. 1, the dielectric reflector 18 is provided on portions of the discontinuous portion 14-1 (as better illustrated in the cross-sectional views of FIGS. 5A-6B). The dielectric reflector 18 may include any material that exhibits increased reflectivity for certain LED emissions compared with the first patterned trace 14, such as at least 60% reflectivity, or at least 80% reflectivity, or at least 90% reflectivity. By way of example, for UV-B and UV-C wavelengths, aluminum may provide at least 90% reflectivity while materials of the first patterned trace 14 may exhibit reflectivity below 40%. As will be later described in greater detail, cover structures may be mounted to the submount 12 with metallurgical bonding materials. While the dielectric reflector 18 may exhibit increased reflectivity, metallurgical bonding materials may have improved adhesion to materials of the first patterned trace 14. In this regard, the dielectric reflector 18 is selectively provided on the first patterned trace 14 to allow cover structure mounting areas with direct access to the first patterned trace 14. In FIG. 1, portions of the discontinuous portion 14-1 that are devoid or uncovered by the dielectric reflector 18 form a cover structure mounting area that is provided about a perimeter of the surface of the submount 12. Accordingly, a cover structure for the LED package 10 may be mounted such that the cover structure contacts the submount 12 only in the cover structure mounting area. In this manner, the dielectric reflector 18 may be provided on a portion of the first patterned trace 14 that is between the die attach pad (e.g., 14-2, 14-3) and the cover structure mounting area. As will be later described in greater detail, the dielectric reflector 18 may alternatively extend across the cover structure mounting area in other embodiments such that all or substantially all of the submount 12 outside of the die attach pad for the LED chip and the attach area for the electrical overstress element is covered by the dielectric reflector 18.

FIG. 2 is a top view of a portion of an LED package 20 that is similar to the LED package 10 of FIG. 1 for an alternative layout of the dielectric reflector 18. As illustrated, the dielectric reflector 18 forms a circular shape on the discontinuous portion 14-1 of the first patterned trace 14. In this regard, the cover structure mounting area that is formed by areas of the discontinuous portion 14-1 that are devoid or uncovered by the dielectric reflector 18 is also provided with a corresponding circular pattern. Such an arrangement may be well suited for cover structures that include domed lenses that are mounted over the submount 12. As with FIG. 1, the dielectric reflector 18 may extend to peripheral edges of the submount 12 to cover all or substantially all of the submount 12 outside of the die attach pad for the LED chip and the attach area for the electrical overstress element is covered by the dielectric reflector 18.

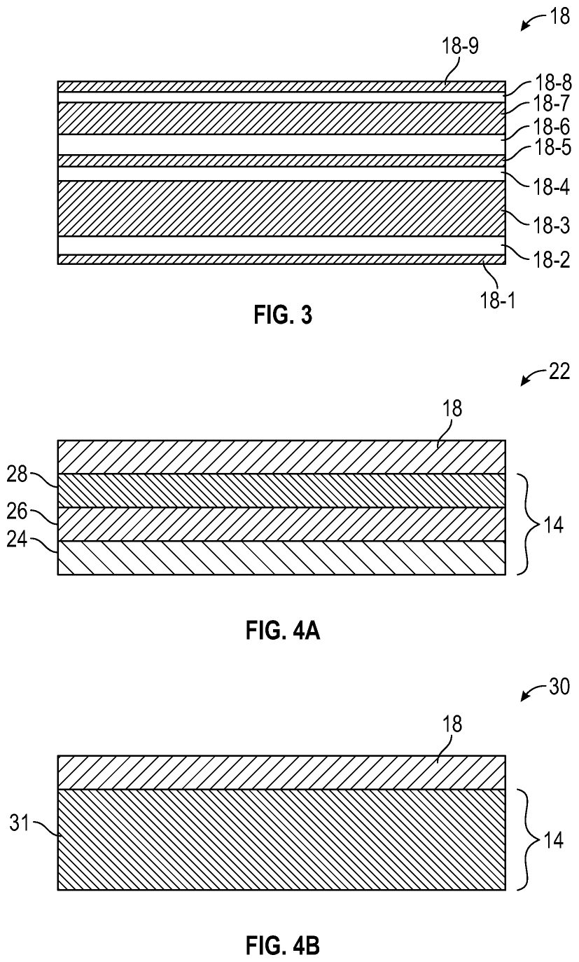

FIG. 3 is a cross-sectional view of an exemplary dielectric reflector 18 that may be provided for any of the previous or forthcoming embodiments of the present disclosure. The dielectric reflector 18 may comprise multiple dielectric layers 18-1 to 18-9 configured to enhance reflection of light from an associated LED chip. In certain embodiments, a material and/or a thickness of individual ones of the dielectric layers 18-1 to 18-9 may be arranged to provide varying optical thicknesses. Optical thickness, which may also be referred to as an optical path length, may be defined as a product of the refractive index of the material and the geometric length a path of light travels through the layer. Accordingly, the optical thickness of an individual layer 18-1 to 18-9 may be changed by increasing or decreasing the actual layer thickness and/or by providing the layer with a different material type than another of the layers 18-1 to 18-9. In certain embodiments, the dielectric layers 18-1 to 18-9 may form layers of alternating optical thicknesses such that the dielectric reflector 18 comprises a distributed Bragg reflector. For example, each of the dielectric layers 18-1, 18-3, 18-5, 18-7, and 18-9 may comprise a first material type while each of the dielectric layers 18-2, 18-4, 18-6, and 18-8 may comprise a second material type with a different refractive index than the first material type.

The dielectric reflector 18 may also form an aperiodic distributed Bragg reflector where optical thicknesses for each of the dielectric layers 18-1 to 18-9 are varied throughout portions of the dielectric reflector 18. In certain embodiments, each individual dielectric layer 18-1 to 18-9 may comprise a unique optical thickness compared to the other dielectric layers 18-1 to 18-9. By way of example, each of the dielectric layers 18-1, 18-3, 18-5, 18-7, and 18-9 may comprise a first material type but relative thicknesses of the dielectric layers 18-1, 18-3, 18-5, 18-7, and 18-9 may vary. In certain embodiments, the dielectric layer 18-3 that is within an interior of the dielectric reflector 18 is the thickest layer, while others of the dielectric layers 18-1, 18-5, 18-7, and 18-9 may also have thicknesses that vary relative to one another. In a similar manner, the dielectric layers 18-2, 18-4, 18-6, and 18-8 may comprise a second material type with a different refractive index than the first material type, and one or more of the dielectric layers 18-2, 18-4, 18-6, and 18-8 may also have thicknesses that vary with respect to one another. In this manner, an interface between each adjacent pair of dielectric layers 18-1 to 18-9 may provide different total internal reflection (TIR) responses based on angles of incident light and wavelength. A dielectric layer with a larger optical thickness (e.g., 18-3) will generally promote TIR of light having shallower angles of incidence than another layer with a smaller optical thickness (e.g., 18-1). In this manner, it may be advantageous to position the layer with the thickest optical thickness (e.g., 18-3) within an interior and spaced away from a top surface of the dielectric reflector 18 or even at a bottom of the dielectric reflector 18 so that light with greater angles of incidence may be redirected earlier, thereby avoiding potential light loss due to internal absorption. Accordingly, a plurality of layers with varying optical thicknesses allows some layers to reflect more light of shallower angles of incidence while having other layers that reflect more light at greater angles of incidence, thus providing the plurality of layers with increased total reflection over all angles.

The materials of the dielectric layers 18-1 to 18-9 may comprise aluminum oxide (Al₂O₃), hafnium oxide (HfO₂), silicon dioxide (SiO₂), zirconium dioxide (ZrO₂), and/or silicon nitride, among others. In the context of UV emissions, dielectric layers 18-1 to 18-9 structured for higher contrast in optical thicknesses and/or higher refractive index differences may be employed to suitably redirect such wavelengths. By way of example, the ability to individually tune the optical thickness of each of the dielectric layers 18-1 to 18-9 may provide reflectance values of at least 97% or in a range from 97% to 99% for UV emissions in a range of 250 nm to 315 nm, or in a range from 200 nm to 315 nm. Such reflectance values exceed conventional metal reflective layers that are commonly employed in UV LED packages. In still further embodiments, the ability to individually tune the optical thickness of each of the dielectric layers 18-1 to 18-9 may also provide the ability to specifically tailor emission patterns and/or wavelength ranges of LED packages.

FIG. 4A is a cross-sectional view of a structure 22 that includes the first patterned trace 14 and the dielectric reflector 18 according to certain embodiments. For illustrative purposes, the dielectric reflector 18 is drawn without the details of FIG. 3, but it is understood the dielectric reflector 18 may include any of the layers 18-1 to 18-9 described above for FIG. 3. FIG. 4A may represent any embodiments of the present disclosure from areas where the dielectric reflector 18 is formed on the first patterned trace 14. As illustrated, the first patterned trace 14 may embody a multiple layer structure, such as a first layer 24, a second layer 26, and a third layer 28 of the first patterned trace 14. In certain embodiments, the first layer 24 may include a layer of Cu and/or alloys thereof, the second layer 26 may include one or more layers of Ni, palladium (Pd), or alloys thereof, and the third layer 28 may comprise a layer of Au. The first patterned trace 14 may include electrolytic layers and may be collectively referred to as an ENEPIG layer. In certain embodiments, a thin adhesion layer, including titanium (Ti) and/or alloys thereof, may be provided on a bottom side of the first layer 24 for adhering to an underlying submount.

FIG. 4B is a cross-sectional view 32 of a structure 30 for an alternative arrangement of the first patterned trace 14 and the dielectric reflector 18. In FIG. 4B, the structure 30 includes a layer 31 that occupies a substantial portion or even all of the first patterned trace 14. In certain embodiments, the thin adhesion layer may be provided on the bottom side of the layer 31. The layer 31 may comprise a layer of Au for Cu-free embodiments. Alternatively, the layer 31 may comprise a layer of Cu with a thin layer of silver on a topside at the interface with the dielectric reflector 18.

FIGS. 5A to 16 are cross-sectional views of LED packages with various configurations of the dielectric reflector 18 and first patterned trace 14 described above. FIGS. 5A to 16 are illustrated with the first patterned trace 14 as described above for FIG. 4A. However, it is understood that the first patterned trace 14 in each of FIGS. 5A to 16 may alternatively comprise the structure described above for FIG. 4B. Additionally, the dielectric reflector 18 of FIGS. 5A to 16 may comprise any of the structures described above for FIG. 3.

FIG. 5A is a cross-sectional view of an LED package 34 taken along a portion of the LED package 34 that is similar to the sectional line A-A of FIG. 1 and where the LED package 34 is assembled with at least one LED chip 36 and a cover structure 38 according to principles of the present disclosure. Depending on the embodiment and the target application, the LED chip 36 may be configured to emit a peak wavelength in any of the visible or UV spectrum, including a peak wavelength in a range from 200 nm to 750 nm, or in a range from 200 nm to 400 nm. As illustrated, the LED chip 36 is mounted on a die attach pad that is formed by portions of the first patterned trace 14 (e.g., portions 14-2, 14-3 of FIG. 1). The vias 16 may extend through an entire thickness of the submount 12 to provide electrical connections between the LED chip 36 on a top face of the submount 12 and corresponding portions of a second patterned trace that are provided on a bottom face of the submount 12. The second patterned trace 15 may be configured to receive external electrical connections for the LED package 34. Additionally, the second patterned trace 15 may be provided with a sufficient surface area across the bottom face of the submount 12 to improve thermal dissipation for the LED package 34. In certain embodiments, the second patterned trace 15 may include a similar arrangement as the first patterned trace 14 such that the first layer 24, the second layer 26, and the third layer 28 are successively provided on the bottom face of the submount 12. In other embodiments, the second patterned trace 15 may include a structure that is different than the first patterned trace 14.

The cover structure 38 may be formed over the LED chip 36 and attached to the first patterned trace 14 at or near a perimeter of the LED package 34. Such an attachment region may be referred to as the cover structure mounting area. The cover structure 38 may include vertical sidewalls that extend to the submount 12 in one or more positions that are below a height of the LED chip 36. In this regard, the cover structure 38 may form a cavity 40 or opening over the LED chip 36 and over the submount 12. In certain embodiments, the cavity 40 may be filled with air and/or nitrogen. In certain embodiments, the cavity 40 may be under a vacuum relative to a surrounding atmosphere, depending on how the cover structure 38 is attached. In certain embodiments, the cover structure 38 forms a hermetic seal for the LED package 34. As illustrated, the cover structure mounting area is defined where the cover structure 38 is attached to the first patterned trace 14 at or near a perimeter of the submount 12. In certain embodiments, the cover structure 38 may form a lens with a domed or hemispherical shape for directing light emissions from the LED chip 36. In certain embodiments, the lens may comprise many different shapes depending on the desired shape of the light output. Suitable shapes include hemispheric, ellipsoid, ellipsoid bullet, cubic, flat, hex-shaped, and square. In certain embodiments, a suitable shape includes both curved and planar surfaces, such as a hemispheric or curved top portion with planar side surfaces. As illustrated in FIG. 5A, ends of the curved top portion of the cover structure 38 may be aligned with corresponding ends of the cavity 40.

While materials of the first patterned trace 14 may provide good adhesion for mounting the LED chip 36 and the cover structure 38, the materials of the first patterned trace 14 may have unsuitable reflectivity, particularly for embodiments where the LED chip 36 provides UV-B and/or UV-C light. In this regard, the dielectric reflector 18 is provided on portions of the first patterned trace 14 that are between the die attach pad of the LED chip 36 and the cover structure mounting area. By arranging the dielectric reflector 18 over portions of the first patterned trace 14 that would be exposed within the cavity 40, increased reflectivity is provided, thereby increasing light emission from the LED package 34. While the dielectric reflector 18 may be configured for all wavelengths of light, including visible and UV, the dielectric reflector 18 may be particularly useful for UV applications where conventional insulating reflective materials, such as a white solder mask, may degrade under UV emissions. As illustrated, at least a portion of the dielectric reflector 18 may be self-aligned to at least one edge of the first patterned trace 14 in certain embodiments.

FIG. 5B is a cross-sectional view of the LED package 34 of FIG. 5A taken along a portion of the LED package 34 that is similar to the sectional line B-B of FIG. 1 in an area that is outside the LED chip 36. As illustrated, the dielectric reflector 18 may be provided along substantially all of the first patterned trace 14 that is outside the LED chip 36 and within the cavity 40 to provide increased reflectivity. In FIGS. 5A and 5B, the dielectric reflector 18 is illustrated with a small gap near the cover structure 38 to provide mounting tolerances for the cover structure 38. In other embodiments, the dielectric reflector 18 may extend entirely from one end of the cavity 40 to the other without any gaps.

FIG. 6A is a cross-sectional view of an LED package 42 that is similar to the LED package 34 of FIGS. 5A and 5B with an alternative arrangement of the cover structure 38. The cross-sectional view provided in FIG. 6A is taken along a similar portion of the LED package 42 as provided for the view of the LED package 34 in FIG. 5A. FIG. 6B is a cross-sectional view of the LED package 42 of FIG. 6A taken along a portion of the LED package 42 that is similar to the sectional line B-B of FIG. 1 in an area that is outside the LED chip 36. The LED package 42 is similar to the LED package 34 of FIGS. 5A and 5B; however, the cover structure 38 forms a flat or planar cover over the submount 12 with vertical sidewalls that extend to the submount 12 in a position that is below a height of the LED chip 36. In this regard, the LED package 42 may be provided with a lower profile for certain applications.

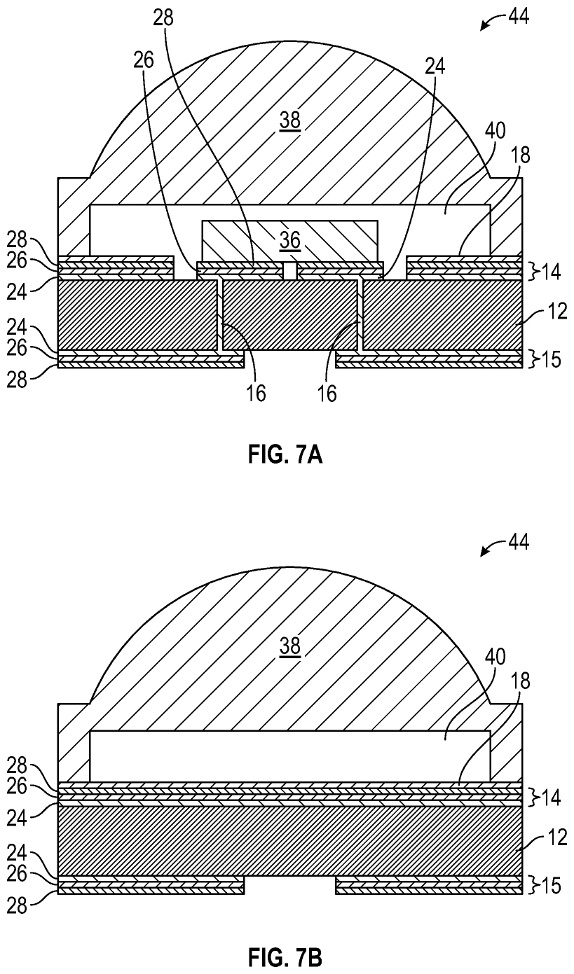

FIG. 7A is a cross-sectional view of an LED package 44 taken along a portion of the LED package 44 that is similar to the sectional line A-A of FIG. 1 and where the dielectric reflector 18 is provided between the cover structure 38 and the submount 12 in the cover structure mounting area according to principles of the present disclosure. FIG. 7B is a cross-sectional view of the LED package 44 of FIG. 7A taken along a portion of the LED package 44 that is similar to the sectional line B-B of FIG. 1. The LED package 44 is similar to the LED package 34 of FIGS. 5A and 5B, except the dielectric reflector 18 extends between the cover structure 38 and the submount 12 in the cover structure mounting area. In this regard, the dielectric reflector 18 may cover an entire area of the first patterned trace 14 that is discontinuous with the die attach pad for the LED chip 36. Such a configuration may be well suited for embodiments where the cover structure 38 comprises a material that does not require metallurgical attachment, such as glass or the like. In this regard, the cover structure 38 may be mounted to portions of the dielectric reflector 18, and in some instances, reflectivity may be increased in the cover structure mounting areas of the LED package 44, particularly for UV applications.

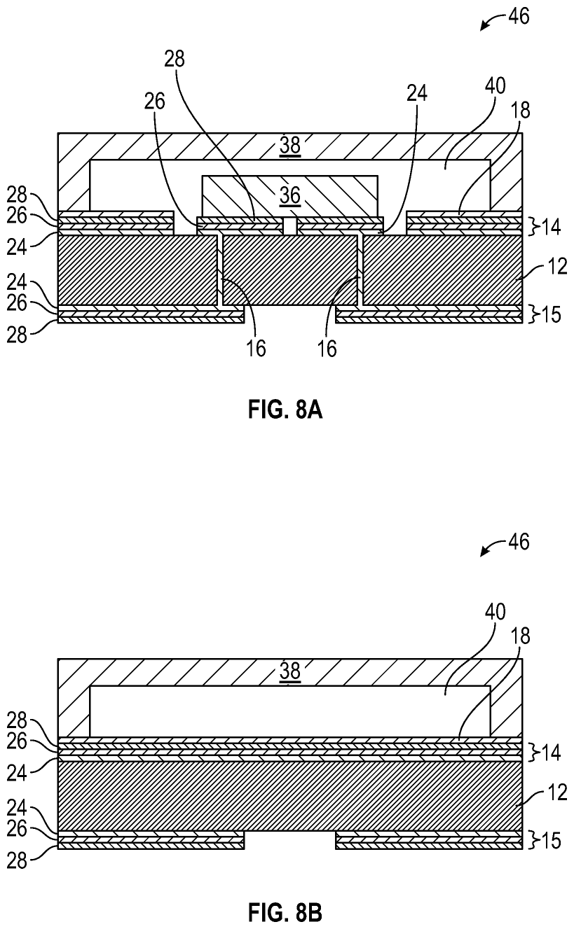

FIG. 8A is a cross-sectional view of an LED package 46 that is similar to the LED package 42 of FIGS. 6A and 6B and where the dielectric reflector 18 is provided between the cover structure 38 and the submount 12 in the cover structure mounting area. The cross-sectional view provided in FIG. 8A is taken along a similar portion of the LED package 46 as provided for the view of the LED package 42 in FIG. 6A. FIG. 8B is a cross-sectional view of the LED package 46 of FIG. 8A taken along a portion of the LED package 46 that is similar to the sectional line B-B of FIG. 1 in an area that is outside the LED chip 36. The LED package 46 is similar to the LED package 44 of FIGS. 7A and 7B for embodiments where the cover structure 38 forms a flat or planar cover over the submount 12 with vertical sidewalls that extend to the submount 12 in a position that is below a height of the LED chip 36. In this regard, the LED package 46 may be provided with a lower profile for certain applications.

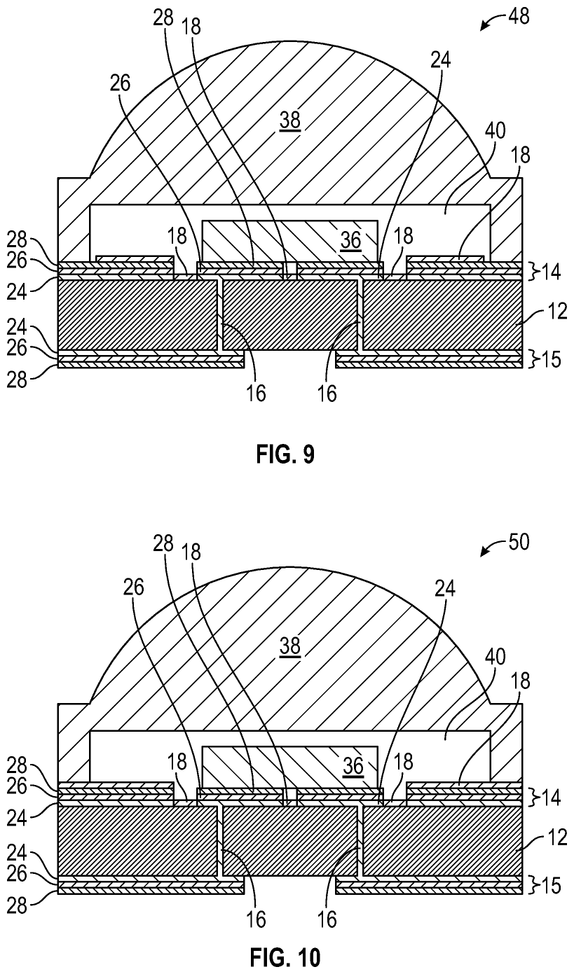

FIG. 9 is a cross-sectional view of an LED package 48 that is similar to FIG. 5A and where the dielectric reflector 18 is further provided on portions of the submount 12 that are laterally adjacent the first patterned trace 14. In this manner, the dielectric reflector 18 may be arranged on portions of the submount 12 without the first patterned trace 14 therebetween. For example, a portion of the dielectric reflector 18 may be on the submount 12 in a position that is in a gap between the discontinuous portions of the first patterned trace 14 that form the die attach pad (e.g., 14-2, 14-3 of FIG. 1). In this manner, the dielectric reflector 18 may be positioned between the LED chip 36 and the submount 12 for reflecting downward propagating light towards the cover structure 38. To avoid topography differences for mounting the LED chip 36, such portion of the dielectric reflector 18 may have a thickness that is less than a thickness of the first patterned trace 14. In certain embodiments, the dielectric reflector 18 may cover portions of the submount 12 that are between other discontinuous portions of the first patterned trace 14 that are outside the die attach area. In FIG. 9, such regions are illustrated to the left and right of the LED chip 36. In this manner, all or substantially all of portions of a floor of the cavity 40, including top surfaces of the first patterned trace 14 and top surfaces of the submount 12 that are uncovered by the first patterned trace 14, may be covered with the dielectric reflector 18 for improved brightness. As further illustrated in FIG. 9, by providing the dielectric reflector 18 within the cover structure mounting area and on portions of the submount 12 that are uncovered by the first patterned trace 14, the dielectric reflector 18 may effectively cover the entire submount 12 except for the portions of the first patterned trace 14 where the LED chip 36 and optional electrical overstress element are mounted. In certain embodiments, the cover structure 38 arrangement of FIG. 6A may be provided for the LED package 48 of FIG. 9 in combination with the arrangement of the dielectric reflector 18 of FIG. 9.

FIG. 10 is a cross-sectional view of an LED package 50 that is similar to the LED package 44 of FIG. 7A and where the dielectric reflector 18 is further provided on portions of the submount 12 that are laterally adjacent the first patterned trace 14. In a similar manner as described above for FIG. 9, the dielectric reflector 18 may be positioned along portions of the submount 12 that are between discontinuous portions of the first patterned trace 14, such as below the LED chip 36 in the gap of the die attach pad and/or along portions of the submount 12 that are adjacent the LED chip 36. Additionally, the dielectric reflector 18 may extend along portions of the first patterned trace 14 such that the dielectric reflector 18 is between the cover structure 38 and the first patterned trace 14. In this manner, the cover structure 38 may be attached to the dielectric reflector 18.

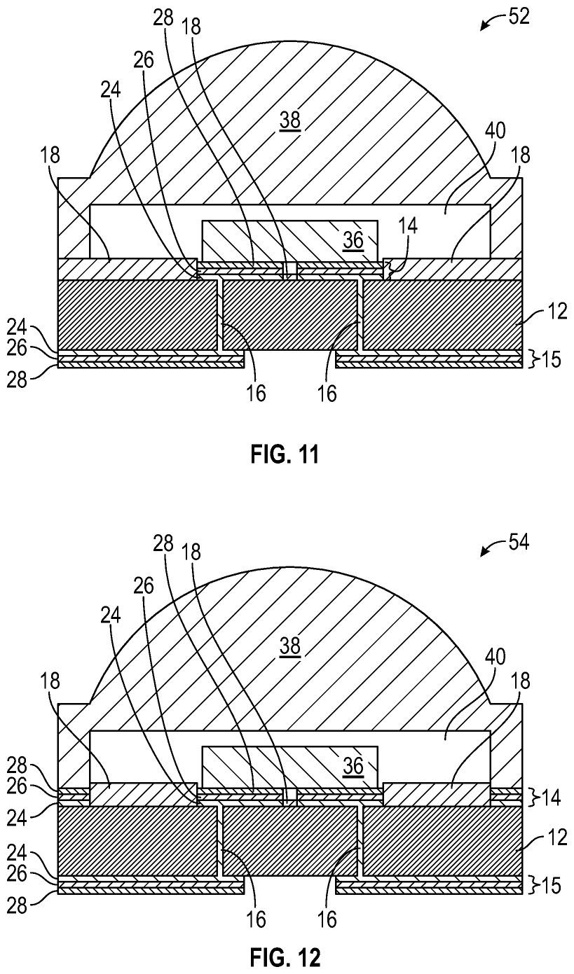

FIG. 11 is a cross-sectional view of an LED package 52 taken along a portion of the LED package 52 that is similar to the sectional line A-A of FIG. 1 and where the first patterned trace 14 is not provided in the cover structure mounting area according to principles of the present disclosure. As illustrated, the first patterned trace 14 may only be provided in areas of the submount 12 that form the die attach pad (e.g., 14-2, 14-3 of FIG. 1). In this regard, the dielectric reflector 18 may be provided on areas of the submount 12 that peripherally surround the LED chip 36 and the first patterned trace 14 and are devoid of the first patterned trace 14. The dielectric reflector 18 may even be arranged to extend to and contact sidewalls of the first patterned trace 14 adjacent the LED chip 36. Accordingly, the cover structure mounting area includes the dielectric reflector 18 and not the first patterned trace 14. As illustrated, the dielectric reflector 18 may include a same or greater thickness as the first patterned trace 14 to facilitate bonding of the cover structure 38. In other embodiments, the dielectric reflector 18 may include a thickness that is less than a thickness of the first patterned trace 14. Additionally, a portion of the dielectric reflector 18 may be provided in the gap between the discontinuous portions of the first patterned trace 14 that form the die attach pad (e.g., 14-2, 14-3 of FIG. 1). To avoid topography differences for mounting the LED chip 36, such portion of the dielectric reflector 18 may have a thickness that is less than a thickness of the first patterned trace 14.

FIG. 12 is a cross-sectional view of an LED package 54 that is similar to the LED package 52 of FIG. 11 except the dielectric reflector 18 is not positioned within the cover structure mounting area. As illustrated, the first patterned trace 14 is provided in an area of the submount 12 for the die attach pad and an area of the submount 12 for the cover structure mounting area. In this regard, the dielectric reflector 18 may cover portions of the submount 12 within the cavity 40 that are uncovered by the first patterned trace 14. In certain embodiments, the dielectric reflector 18 may even be arranged to extend to and contact sidewalls of the first patterned trace 14 adjacent the LED chip 36 and the cover structure mounting area.

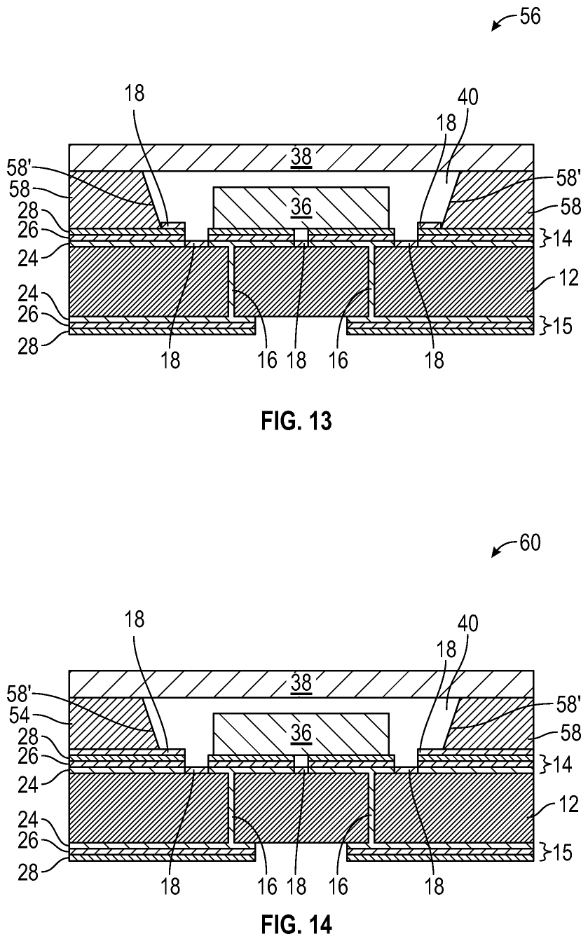

FIG. 13 is a cross-sectional view of an LED package 56 taken along a portion of the LED package 56 that is similar to the sectional line A-A of FIG. 1 and wherein the LED package 56 includes a reflector structure 58 arranged between the cover structure 38 and the submount 12. In certain embodiments, the reflector structure 58 is a separate element that may be mounted or otherwise attached to one or more of the first patterned trace 14 and the submount 12. As illustrated, the cover structure 38 may be attached to the reflector structure 58, and the reflector structure 58 and cover structure 38 are attached to the cover structure mounting area that is provided around a periphery of the LED chip 36. In FIG. 13, the cover structure mounting area of the submount 12 may be defined as where the reflector structure 58 is mounted to the first patterned trace 14. The reflector structure 58 may comprise internal sidewalls 58′ that define lateral boundaries of the cavity 40. In certain embodiments, the sidewalls 58′ may be angled with respect to the submount 12 to redirect laterally emitted light from the LED chip 36 through the cover structure 38 in a desired emission direction for the LED package 56. In other embodiments, the sidewalls 58′ may form a vertical sidewall that is substantially perpendicular with the submount 12 while still redirecting lateral light emissions from the LED chip 36.

The reflector structure 58 may include a material with a sufficient coefficient of thermal expansion (CTE) relative to other portions of the LED package 56. In certain embodiments, the reflector structure 58 comprises silicon and may optionally have a metal coating, for example aluminum or alloys thereof, on the sidewalls 58′. In other embodiments, the entire reflector structure 58 may comprise a metal, such as aluminum or alloys thereof. In still other embodiments, the reflector structure 58 may comprise a ceramic, such as one or more of aluminum oxide (Al₂O₃), zirconium dioxide (ZrO₂), silicon dioxide (SiO₂), and aluminum nitride (AlN). For embodiments where the reflector structure 58 comprises a ceramic material, the sidewalls 58′ may be coated with a metal as described above for added reflectivity. As illustrated, the dielectric reflector 18 is provided on exposed portions of the first patterned trace 14 within the cavity 40 to provide increased reflectivity. The dielectric reflector 18 may also be arranged on portions of the submount 12 that are between discontinuous portions of the first patterned trace 14, such as below the LED chip 36 in the die attach area and/or adjacent the LED chip 36. While the cover structure 38 is illustrated as planar in FIG. 13, the cover structure 38 may form a lens with a domed or hemispherical shape for directing light emissions from the LED chip 36.

FIG. 14 is a cross-sectional view of an LED package 60 that is similar to the LED package 56 of FIG. 13 and where the dielectric reflector 18 extends on the first patterned trace 14 in a position that is between the reflector structure 58 and the submount 12. In this regard, the reflector structure 58 may be bonded directly to the dielectric layer 18. Having the dielectric reflector 18 extend across the first patterned trace 14 and portions of the submount 12 as illustrated may provide simplified manufacturing steps and may also provide electrical isolation between the reflector structure 58 and the dielectric reflector 18.

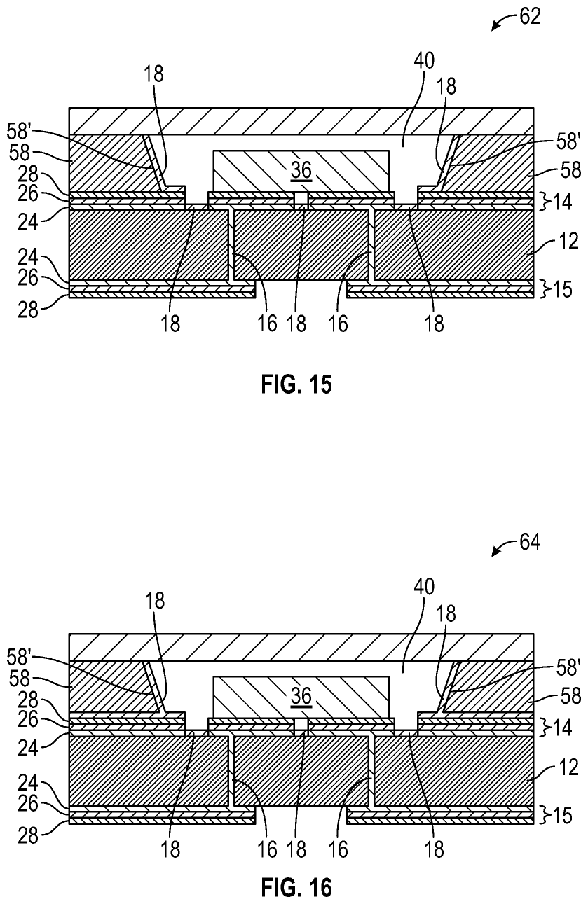

FIG. 15 is a cross-sectional view of an LED package 62 that is similar to the LED package 56 of FIG. 13 and where the dielectric reflector 18 extends along the sidewalls 58′ of the reflector structure 58. In this manner, the dielectric reflector 18 may cover a floor and the sidewalls 58′ that bound the cavity 40 for increased reflectivity. In such embodiments, the dielectric reflector 18 may be formed within the LED package 62 after the reflector structure 58 is attached and before the LED chip 36 is provided. As with other embodiments, the dielectric reflector 18 may also be arranged on portions of the submount 12 that are between discontinuous portions of the first patterned trace 14, such as below the LED chip 36 in the die attach area and/or adjacent the LED chip 36.

FIG. 16 is a cross-sectional view of an LED package 64 that is similar to the LED package 62 of FIG. 15 and where the dielectric reflector 18 extends along the sidewalls 58′ of the reflector structure 58 and between the reflector structure 58 and the first patterned trace 14. In this manner, portions of the dielectric reflector 18 on the first patterned trace 14 and the submount 12 may be formed before the reflector structure 58 is attached and the portion of the dielectric reflector 18 on the sidewalls 58′ may be formed after the reflector structure 58 is attached to the submount 12.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a submount comprising a first face and a second face that opposes the first face;
at least one LED chip on the first face of the submount;
a cover structure arranged over the at least one LED chip;
a patterned trace on the first face of the submount, the cover structure being attached to the patterned trace at a cover structure mounting area that is outside of at least one die attach pad; and
a dielectric reflector on a portion of the patterned trace that is between the at least one die attach pad and the cover structure mounting area, the dielectric reflector comprising a distributed Bragg reflector.

2. The LED package of claim 1, wherein the distributed Bragg reflector is an aperiodic distributed Bragg reflector.

3. The LED package of claim 2, wherein:
the aperiodic distributed Bragg reflector comprises a plurality of dielectric layers; and
each dielectric layer of the plurality of dielectric layers comprises a unique optical thickness relative to other dielectric layers of the plurality of dielectric layers.

4. The LED package of claim 3, wherein the plurality of dielectric layers comprises alternating dielectric layers of a first material type and a second material type.

5. The LED package of claim 1, wherein the dielectric reflector is further on a portion of the submount that is uncovered by the patterned trace and the at least one LED chip.

6. The LED package of claim 5, wherein the dielectric reflector is further arranged between the at least one LED chip and the submount in a gap formed by the patterned trace along the at least one die attach pad.

7. The LED package of claim 6, wherein the at least one LED chip is configured to provide a peak wavelength in a range from 200 nm to 400 nm.

8. A light-emitting diode (LED) package comprising:
a submount comprising a first face and a second face that opposes the first face;
at least one LED chip on the first face of the submount;
a cover structure arranged over the at least one LED chip, the cover structure being mounted to the submount at a cover structure mounting area that is spaced from a peripheral boundary of the at least one LED chip;
a patterned trace on the first face of the submount, the patterned trace forming at least one die attach pad for the at least one LED chip; and
a dielectric reflector on a portion of the submount that is laterally adjacent the patterned trace, the dielectric reflector comprising a distributed Bragg reflector.

9. The LED package of claim 8, wherein the dielectric reflector is further arranged on a portion of the patterned trace.

10. The LED package of claim 8, wherein the dielectric reflector is further arranged between the cover structure and the submount at the cover structure mounting area.

11. The LED package of claim 8, wherein:
the distributed Bragg reflector is an aperiodic distributed Bragg reflector;
the aperiodic distributed Bragg reflector comprises a plurality of dielectric layers; and
each dielectric layer of the plurality of dielectric layers comprises a unique optical thickness relative to other dielectric layers of the plurality of dielectric layers.

12. The LED package of claim 11, wherein the plurality of dielectric layers comprises alternating dielectric layers of a first material type and a second material type.

13. The LED package of claim 11, wherein a dielectric layer with a largest optical thickness of the plurality of dielectric layers is positioned to be spaced away from a top surface of the aperiodic distributed Bragg reflector and within an interior of the aperiodic distributed Bragg reflector.

14. The LED package of claim 8, wherein the at least one LED chip is configured to provide a peak wavelength in a range from 200 nm to 400 nm.

15. A light-emitting diode (LED) package comprising:
a submount comprising a first face and a second face that opposes the first face;
at least one LED chip on the first face of the submount;
a patterned trace on the first face of the submount; and
a dielectric reflector on a portion of the patterned trace and on a portion of the submount that is laterally adjacent the patterned trace, the dielectric reflector comprising a distributed Bragg reflector.

16. The LED package of claim 15, wherein the distributed Bragg reflector is an aperiodic distributed Bragg reflector.

17. The LED package of claim 16, wherein:
the aperiodic distributed Bragg reflector comprises a plurality of dielectric layers; and
each dielectric layer of the plurality of dielectric layers comprises a unique optical thickness relative to other dielectric layers of the plurality of dielectric layers.

18. The LED package of claim 17, wherein the plurality of dielectric layers comprises alternating dielectric layers of a first material type and a second material type.

19. The LED package of claim 17, wherein a dielectric layer with a largest optical thickness of the plurality of dielectric layers is positioned to be spaced away from a top surface of the aperiodic distributed Bragg reflector and within an interior of the aperiodic distributed Bragg reflector.

20. The LED package of claim 15, wherein:
the patterned trace comprises at least one die attach pad for the at least one LED chip; and
the dielectric reflector is further arranged between the at least one LED chip and the submount in a gap formed by the patterned trace along the at least one die attach pad.

21. The LED package of claim 15, wherein the at least one LED chip is configured to provide a peak wavelength in a range from 200 nm to 400 nm.

22. The LED package of claim 15, further comprising a cover structure arranged over submount to form a cavity over the at least one LED chip.

23. The LED package of claim 22, further comprising a reflector structure arranged between the cover structure and the submount, wherein a sidewall of the reflector structure bounds a portion of the cavity.

24. The LED package of claim 23, wherein the dielectric reflector is arranged on the sidewall of the reflector structure.

25. The LED package of claim 23, wherein the dielectric reflector is arranged between the reflector structure and the submount.
